(19) United States
(12) Patent Application Publication
(10) Pub. No.: US 2021/0398837 A1
(43) Pub. Date: Dec. 23, 2021

(54) SYSTEM AND METHOD FOR ALIGNING MICRO LIGHT-EMITTING DIODES

(71) Applicant: Innostar Service, Inc., Taichung (TW)

(72) Inventor: Meng-Chih WU, Taichung (TW)

(21) Appl. No.: 16/904,565

(22) Filed: Jun. 18, 2020

(51) Int. Cl. H01L 21/677; H01L 21/673; B65G 47/90

(52) U.S. Cl. CPC H01L 21/67793; B65G 47/90; H01L 21/67333

(57) ABSTRACT

A method is provided for aligning micro light-emitting diodes. A platform is provided with arrays. Each of the arrays includes grooves. The platform is used to receive magnetic micro light-emitting diodes. Magnetic attraction and vibration are alternately exerted on the platform to cause the magnetic micro light-emitting diodes to fall into the grooves in a correct orientation. It is determined whether the magnetic micro light-emitting diodes fill the platform. Mass transfer is executed if the magnetic micro light-emitting diodes fill the platform.

### BACKGROUND OF INVENTION

### 1. Field of Invention

The present invention relates to light emitting diodes in the order of micron (1×10⁻³ mm) and, more particularly, to a system and method for aligning grains of micro light-emitting diodes to facilitate mass transfer.

### 2. Related Prior Art

A micro light-emitting diode is different from an ordinary light-emitting diode in the size of grain. The size of a grain of an ordinary light-emitting diode is 100 to 1000 μm, with thickness of 100 to 500 μm. The size of a grain of a micro light-emitting diode is smaller than 100 μm, with thickness of 4 to 5 μm.

Ingentec Corporation has developed a method for making grains of vertical-type light-emitting diodes. An epitaxial layer is grown on a growth substrate. The epitaxial layer is connected to a metallic laminate. Multiple electrode units are provided on the epitaxial layer after the growth substrate is removed. Then, the combination of the electrode units with the epitaxial layer is cut into grains of micro light-emitting diodes. Each micro light-emitting diode includes an epitaxial grain. The epitaxial grain includes a metallic laminate on a side and an electrode unit layer on another side. The metallic laminate exhibits magnetic permeability to facilitate mass transfer of micro light-emitting diodes. The so called mass transfer of light-emitting diodes is a process of transferring a large amount of grains of micro light-emitting diodes to a single display substrate after the completion of the production of the epitaxial grains.

In commercial application, an objective is to precisely transfer a large amount of micro light-emitting diodes to a display substrate from an epitaxial substrate in a reasonable period of time. For example, a display (or “4K television set”) that exhibits a horizontal resolution of 4000 pixels and a vertical resolution of 2000 pixels needs about 24 million grains of RGB micro light-emitting diodes. It takes about 2400 rounds of transfer if 10000 grains are transferred in each round. It requires precision to pick up, transfer and lay down a large amount of grains of micro light-emitting diodes in the mass transfer of the micro light-emitting diodes.

Many techniques have been developed for mass transfer such as electrostatic transfer techniques and adhesive transfer techniques.

In an electrostatic transfer technique, multiple electrostatic transfer heads are arranged in an array. Electrostatic attraction is used to pick up micro light-emitting diodes so that they can be moved. After reaching a destination, the electrostatic attraction is turned off to lay down the micro light-emitting diodes.

In an adhesive transfer technique, there is provided an array of stabilizing chambers. Each of the stabilizing chambers includes walls extending from a lower portion. The walls are tilted to define an opening larger than an opening in the lower portion of each of the stabilizing chambers. Stabilizing axles extend from the stabilizing chambers. Micro light-emitting diodes are adhered to free ends of the stabilizing axles and kept in the stabilizing chambers. Thus, the micro light-emitting diodes are picked up.

Alternatively, in a transfer technique, an impression element is made of elastomer and used to capture an array of micro light-emitting diodes. Speed of movement of the impression element is changed to adjust a force (Van der Waals force) for adhesion of the impression element to the micro light-emitting diodes to release the micro light-emitting diodes.

Moreover, the applicant of the present application has devised a method for transferring a batch of micro elements such as micro light-emitting diodes. A transportation tool is equipped with an array of needles. The needles stick out of a lower portion of the transportation tool. The transportation tool includes a temperature-controlling channel to change the temperature of the needles so that the micro elements can be attracted to the tips of the needles.

However, none of these techniques addresses how to align the micro light-emitting diodes. Therefore, the present invention is intended to obviate or at least alleviate the problems encountered in the prior art.

### SUMMARY OF INVENTION

It is an objective of the present invention to provide a method for aligning magnetic micro light-emitting diodes.

To achieve the foregoing objective, the method is provided for aligning micro light-emitting diodes. A platform is provided with arrays. Each of the arrays includes grooves. The platform is used to receive magnetic micro light-emitting diodes. Magnetic attraction and vibration are alternately exerted on the platform to cause the magnetic micro light-emitting diodes to fall into the grooves in a correct orientation. It is determined whether the magnetic micro light-emitting diodes fill the platform. Mass transfer is executed if the magnetic micro light-emitting diodes fill the platform.

It is another objective of the present invention to provide a system for aligning magnetic micro light-emitting diodes.

To achieve the foregoing objective, the system includes a table, a platform, a camera, operative rods, magnets and two vibrators. The platform is supported on the table and includes grooves corresponding to the micro light-emitting diodes. The camera is supported on the table above the platform and operable to take photographs of the grooves and send the photographs to a computer. The operative rods are supported on the table and operable to tilt the platform. The operative rods are alternately actuated to move the platform along a z-axis to flip over the micro light-emitting diodes if so desired. The magnets are supported on the table corresponding to the grooves of the platform. The vibrators are supported on the table and operable to vibrate the platform in an x-axis and a y-axis, respectively.

Other objectives, advantages and features of the present invention will be apparent from the following description referring to the attached drawings.

### BRIEF DESCRIPTION OF DRAWINGS

The present invention will be described via detailed illustration of two embodiments referring to the drawings wherein:

FIG. 1 is a flow chart of a micro-aligning method according to the first embodiment of the present invention;

FIG. 2 is a perspective view of a micro-aligning system according to the second embodiment of the present invention;

FIG. 3 is a side view of the micro-aligning system shown in FIG. 2;

FIG. 4 is a cross-sectional view of the micro-aligning system taken along a line A-A shown in FIG. 3;

FIG. 5 is an enlarged top view of a substrate on the micro-aligning system shown in FIG. 2;

FIG. 6 is an enlarged top view of an array formed on the substrate shown in FIG. 5; and

FIG. 7 is an enlarged cross-sectional view of the array taken along a line B-B shown in FIG. 6.

### DETAILIGHT-EMITTING DIODES DESCRIPTION OF EMBODIMENTS

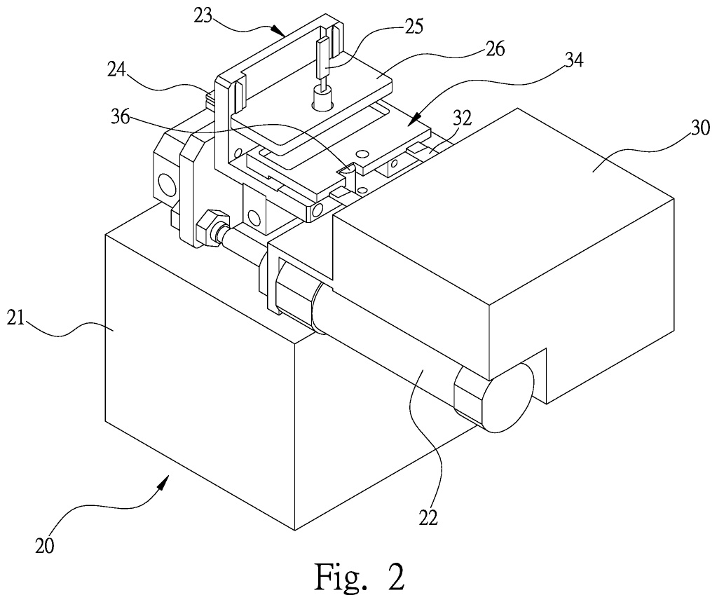

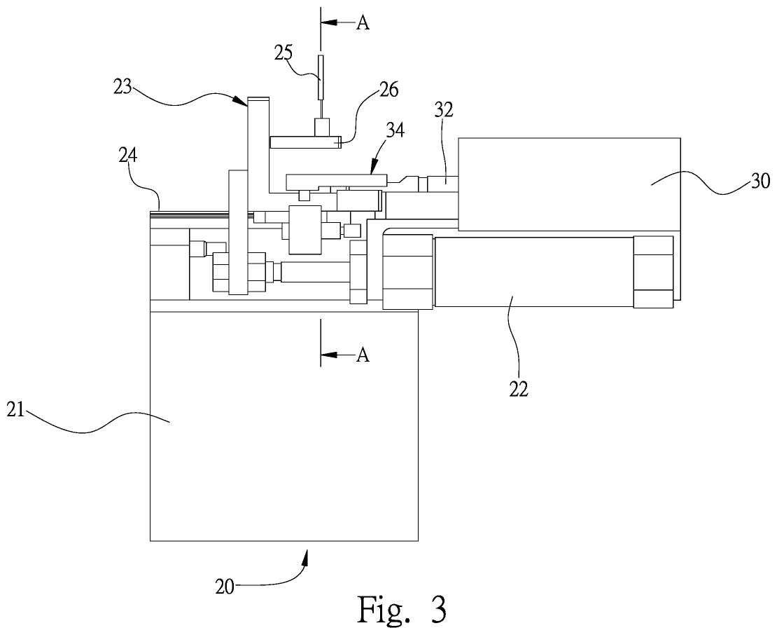

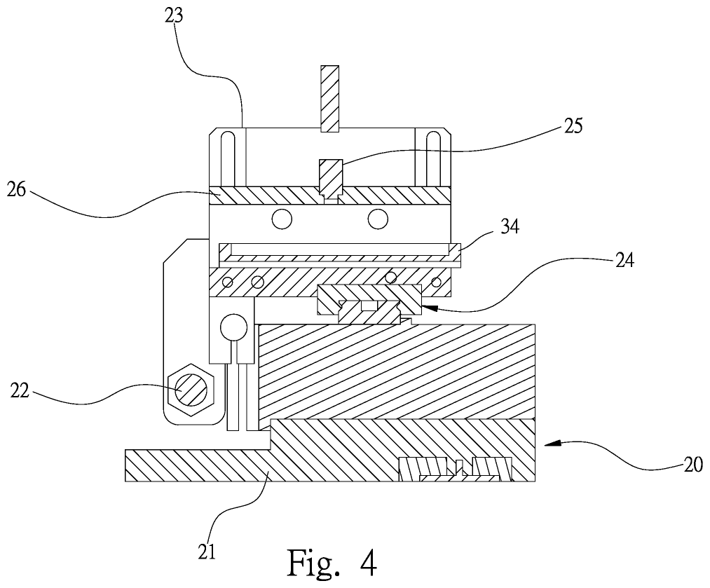

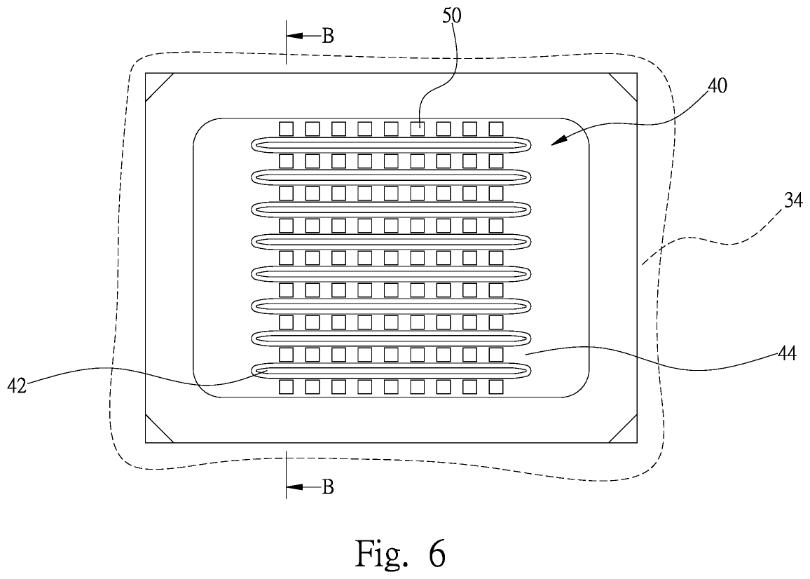

Referring to FIGS. 2 to 4, a micro-aligning system 20 includes a table 21, a cylinder 22, a vehicle 23, a track 24, a camera 25 and an elevator 26 according to an embodiment of the present invention. The table 21 is supported on a floor. The cylinder 22 is a pneumatic or hydraulic cylinder supported on the table 21. The vehicle 23 is connected to a mandrel (not numbered) of the cylinder 22. The track 24 is supported on the table 21. The cylinder 22 is operable to move the vehicle 23 to and forth along the track 24 on the table 21. The elevator 26 is supported on the vehicle 23. The camera 25 is connected to the elevator 26. The elevator 26 is move the camera 25 to the height of a platform 34 of the vehicle 23. The camera 25 is located above the platform 34. A motor (not shown) is used to rotate the camera 25 about a vertical axis to take photographs of the platform 34. By cables or in a wireless manner, the photographs are transferred to a computer for example. The computer runs a software program to identify the status of the platform 34 that receives micro light-emitting diodes 50 (FIG. 6).

In addition, the table 21 is equipped with an adjustor 30. The adjustor 30 includes two operative rods 32 extending parallel to each other. The operative rods 32 extend toward the vehicle 23 for a certain distance. Each of the operative rods 32 is in contact with or pivotally connected to a corresponding portion of the platform 34.

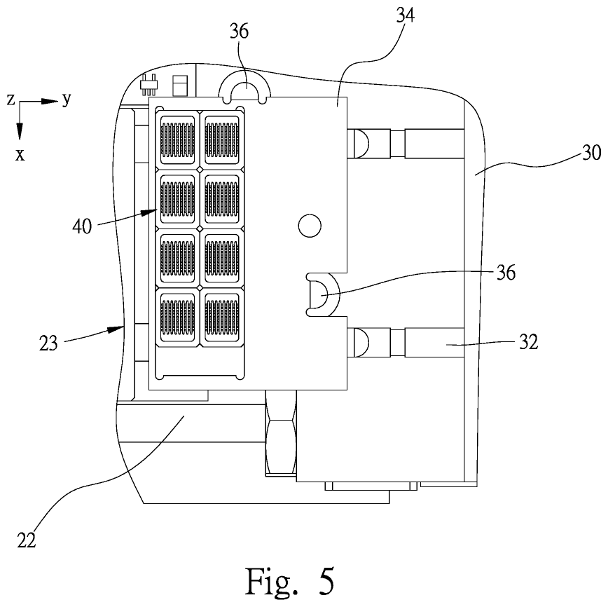

Referring to FIG. 5, the platform 34 is movable along x-axis, y-axis and z-axis. The operative rods 32 can synchronously be actuated to move portions of the platform 34 along the z-axis so that the platform 34 is horizontal or tilted. Alternatively, each of the operative rods 32 can be moved along the z-axis in dependent of the other operative rod 32 to lift or lower a portion of the platform 34 so that the platform 34 is tilted. The operative rods 32 can alternately be actuated to vibrate the platform 34 along the z-axis.

Two vibrators 36 are supported on the table 21. One of the vibrators 36 is located between the operative rods 32 to vibrate the platform 34 along the y-axis. The other vibrator 36 is actuated to vibrate the platform 34 along the x-axis.

Each of the vibrators 36 is a mandrel of a pneumatic cylinder or a cam operatively connected to a motor. The amplitude of the vibration of the platform 34 by the vibrators 36 is under control mechanically.

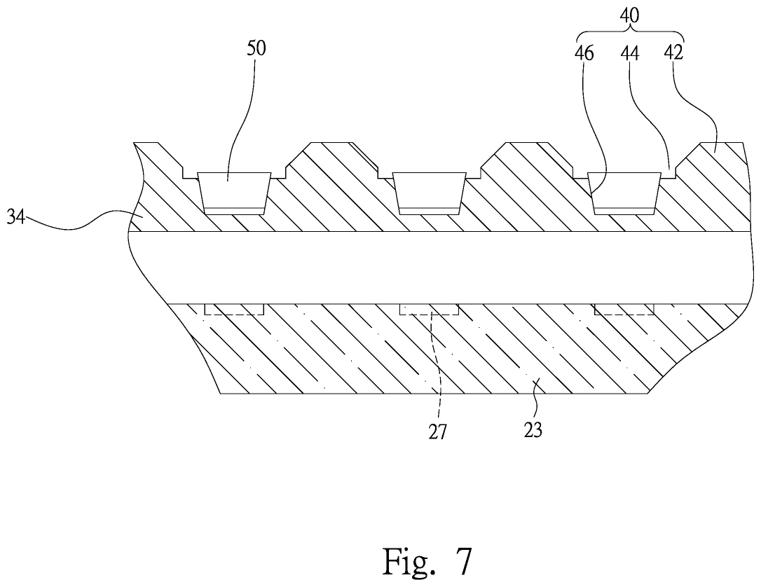

Referring to FIG. 6, laser etching, 3D printing or any other proper means can be used to form multiple arrays 40 on the platform 34. Each of the arrays 40 includes multiple ridges 42 extending upward from an upper face of the platform 34. The ridges 42 for multiple passages 44 on the upper face of the platform 34. Each of the passages 44 is an elongated region of the upper face of the platform 34. Each of the passages 44 includes a groove 46 (FIG. 7). Each of the grooves 46 gets narrower as it goes deeper. The grooves 46 are shaped in compliance with the micro light-emitting diodes 50.

Any two adjacent ones of the ridges 42 are used to restrain one of the micro light-emitting diodes 50 from two sides. Thus, each of the micro light-emitting diodes 50 is only movable along a corresponding one of the passages 44 on the platform 34.

Referring to FIG. 7, multiple magnets 27 are inserted in the vehicle 23. Each of the magnets 27 is a magnetostatic or electromagnet. Each of the magnets 27 is located corresponding to a corresponding one of the grooves 46 of the platform 34.

Such a magnetostatic element exerts a magnetic force without having to consume any electricity. The location of such a magnetostatic element can be changed to change the intensity of its magnetic force.

Such an electromagnet is energized by electricity to exert a magnetic force. A current for energizing such an electromagnet can be changed to change the intensity of its magnetic force.

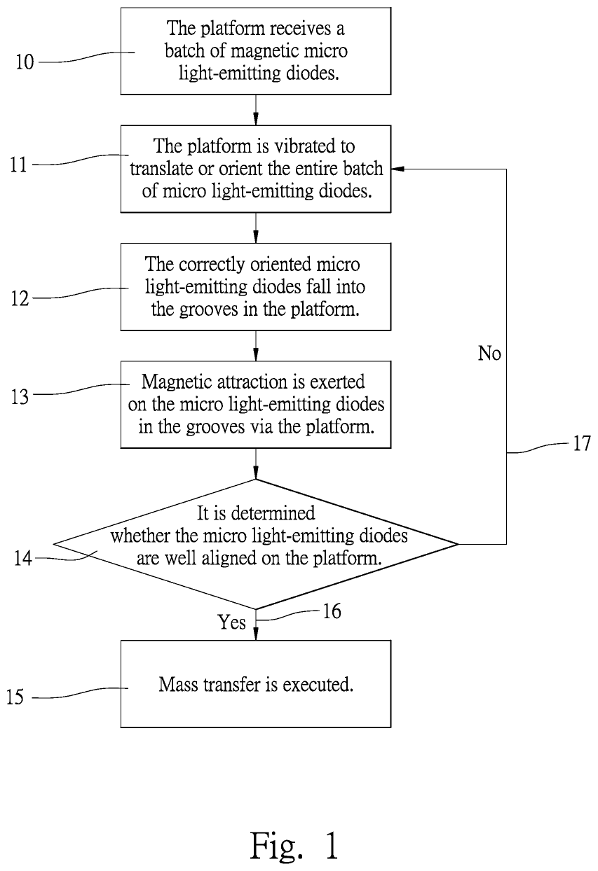

Referring to FIGS. 1, 2 and 5 through 7, a micro-aligning method according to another embodiment of the present invention will be described.

At 10, the platform 34 receives a batch of magnetic micro light-emitting diodes 50. A transporting tool (not shown) can be used to transport the entire batch of micro light-emitting diodes 50 onto platform 34.

A grain of each of the micro light-emitting diodes 50 is connected to a metallic laminate on a side and connected to an electrode unit on another side. The metallic laminate is magnetically permeable. Thus, the micro light-emitting diodes 50 are magnetically permeable.

The transporting tool includes at least one vibrating tray (not shown) for vibrating the micro light-emitting diodes 50, thereby moving the micro light-emitting diodes 50 onto the platform 34. Thus, piling of the micro light-emitting diodes 50 is avoided. Inevitably, some of the micro light-emitting diodes 50 are defective. Such a vibrating tray can disperse such defective ones among the micro light-emitting diodes 50.

At 11, the platform 34 is vibrated to translate or orient the entire batch of micro light-emitting diodes 50.

About the translation of the micro light-emitting diodes 50, one of the vibrators 36 vibrates the platform 34 along the x-axis and hence moves the micro light-emitting diodes 50 along the passages 44. The other vibrator 36 vibrates the platform 34 along the y-axis to move the micro light-emitting diodes 50 perpendicular to the passages 44. If necessary, the operative rods 32 can change the tilting of the platform 34 and hence speed up movement of the micro light-emitting diodes 50 on the platform 34.

Regarding the orientation of the micro light-emitting diodes 50, when the micro light-emitting diodes 50 are upside down or disoriented, the operative rods 32 are alternately actuated to move the platform 34 along the z-axis. Thus, the micro light-emitting diodes 50 are flipped over or moved to a correct orientation on the platform 34.

That is, the foregoing process is executed to vibrate and move the micro light-emitting diodes 50 to the correct location and orientation on the platform 34, which is horizontal or tilted.

At 12, the correctly oriented micro light-emitting diodes 50 fall into the grooves 46 in the platform 34. A reduced lower portion of each of the micro light-emitting diodes 50 reaches a reduced lower portion of the corresponding groove 46. The arrays 40 enable the platform 34 to receive a large amount of micro light-emitting diodes 50.

At 13, magnetic attraction is exerted on the micro light-emitting diodes 50 in the grooves 46 via the platform 34. The magnets 27 magnetically attract the micro light-emitting diodes 50 in the grooves 46, thereby keeping the micro light-emitting diodes 50 in the grooves 46 against the vibration that could otherwise cause the micro light-emitting diodes 50 to jump back onto the upper face of the platform 34 from the grooves 46.

At 14, it is determined whether the micro light-emitting diodes 50 are well aligned on the platform 34. The camera 25 is used to take photographs of the platform 34 and transmit the photographs to the computer. The computer compares the photographs with a default to determine whether the micro light-emitting diodes 50 are well aligned.

The process goes to 16 if the micro light-emitting diodes 50 fill 99% of the grooves 46 of the platform 34. Then, the process goes to 15.

The process goes to 17 if otherwise, i.e., the micro light-emitting diodes 50 fail to fill 99% of the grooves 46 of the platform 34. Then, the process will be repeated. The process will be executed once and again until the process finally goes to 16, i.e., the micro light-emitting diodes 50 fill 99% of the grooves 46 of the platform 34.

At 15, mass transfer is executed. The transfer unit equipped with probes (not shown) corresponding to the array 40 is used to transfer the micro light-emitting diodes 50 to a predetermined location from the arrays 40. Thus, the micro-aligning system 20 executes the micro-aligning method for successful mass production and mass transfer.

It should be noted that the steps represented by “11”, “12” and “13” are combined with one another to provide a subroutine of alternate magnetic attraction and vibration to cause the grooves 46 of the platform 34 to capture correctly located and oriented micro light-emitting diodes 50. These steps can be arranged in any other proper order.

The subroutine is executed for only once if the grooves 46 of the platform 34 are used to capture micro light-emitting diodes 50 of one color. However, the subroutine is executed for three times if the grooves 46 of the platform 34 are used to capture micro light-emitting diodes 50 of three colors, i.e., RGB.

For example, the micro light-emitting diodes 50 are of red. At 10, the vibrating tray is used to disperse defective micro light-emitting diodes 50 among the micro light-emitting diodes 50 and then transport the micro light-emitting diodes 50 onto the platform 34. At 11, vibration is imposed on the platform 34 to correctly locate and orient the micro light-emitting diodes 50 on the platform 34. At 12, the correctly located and oriented micro light-emitting diodes 50 are inserted into the grooves 46 of the platform 34. At 13, magnetic attraction is used to keep the micro light-emitting diodes 50 in the grooves 46 of the platform 34.

At 14, it is determined whether the micro light-emitting diodes 50 are well aligned on the platform 34. The process goes to 16 if the micro light-emitting diodes 50 fill 99% of the grooves 46 of the platform 34. Then, the process goes to 15. The process goes to 17 if otherwise. Then, the subroutine will be repeated. The process will be executed once and again until the process finally goes to 16. At 15, mass transfer is executed.

To capture micro light-emitting diodes 50 of red, green and blue, the subroutines is executed for three rounds. Firstly, the magnets 27 are used to move the micro light-emitting diodes 50 of red into first one-third of the grooves 46 of the platform 34. The micro light-emitting diodes 50 that are not captured in the first one third of the grooves 46 are swept.

Secondly, the magnets 27 are used to move the micro light-emitting diodes 50 of green into second one-third of the grooves 46 of the platform 34. The micro light-emitting diodes 50 that are not captured in the two thirds of the grooves 46 are swept.

Thirdly, the magnets 27 are used to move the micro light-emitting diodes 50 of blue into third one-third of the grooves 46 of the platform 34. The micro light-emitting diodes 50 that are not captured in the grooves 46 are swept.

Finally, mass transfer is executed for only once.

The present invention has been described via the illustration of the embodiments. Those skilled in the art can derive variations from the embodiments without departing from the scope of the present invention. Therefore, the embodiments shall not limit the scope of the present invention defined in the claims.

1. A method for aligning micro light-emitting diodes comprising the steps of:
providing a platform with arrays, wherein each of the arrays comprises grooves;
using the platform to receive magnetic micro light-emitting diodes;
alternately exerting magnetic attraction and vibration on the platform to cause the magnetic micro light-emitting diodes to fall into the grooves in a correct orientation;
determining whether the magnetic micro light-emitting diodes fill the platform; and
executing mass transfer if the magnetic micro light-emitting diodes fill the platform.

2. The method according to claim 1, wherein the step of alternately exerting magnetic attraction and vibration comprises the steps of:
vibrating the platform to translate and orient the magnetic micro light-emitting diodes;
sending the magnetic micro light-emitting diodes into the grooves of the platform; and
exerting magnetic attraction on the magnetic micro light-emitting diodes to keep the magnetic micro light-emitting diodes in the grooves of the platform.

3. The method according to claim 1, further comprising the step of using a vibrating tray to transport the magnetic micro light-emitting diodes to the platform.

4. The method according to claim 1, wherein the magnetic attraction is selected from the group of magnetostatic attraction and electromagnetic attraction.

5. The method according to claim 1, further comprising the step of using passages on the platform, wherein each of the passages comprises a row of the grooves, wherein the magnetic micro light-emitting diodes go into the grooves via the passages.

6. The method according to claim 1, the step of determining whether the magnetic micro light-emitting diodes fill the platform comprises the step of providing a camera to take photographs of the platform and compare the photographs with a default.

7. A system for aligning micro light-emitting diodes comprising:
a table;
a platform supported on the table, wherein the platform comprises grooves corresponding to the micro light-emitting diodes;
a camera supported on the table above the platform and operable to take photographs of the grooves and send the photographs to a computer;
operative rods supported on the table and operable to tilt the platform, wherein the operative rods are alternately actuated to move the platform along a z-axis to flip over the micro light-emitting diodes if so desired;
magnets supported on the table corresponding to the grooves of the platform; and
two vibrators supported on the table and operable to vibrate the platform in an x-axis and a y-axis, respectively.

8. The system according to claim 7, wherein the platform comprises ridges to provide passages on the platform, wherein each of the passages comprises a row of the grooves of the platform, wherein each of the passages extends between two adjacent ones of the ridges so that the micro light-emitting diodes are only movable along the passages on the platform.

9. The system according to claim 7, further comprising a vehicle for carrying the platform on the table and a cylinder connected to the vehicle at an end and connected to the table at another end.

10. The method according to claim 7, wherein the magnets are selected from the group consisting of magnetostatic elements and magnets.
